(19) United States
(12) Patent Application Publication
(10) Pub. No.: US 2014/0063702 A1
(43) Pub. Date: Mar. 6, 2014

(54) DISPLAY APPARATUS

(71) Applicant: Sony Corporation, Tokyo (JP)

(72) Inventors: Daisuke Nezu, Tokyo (JP); Daisuke Shiono, Tokyo (JP)

(73) Assignee: Sony Corporation, Tokyo (JP)

(21) Appl. No.: 13/966,579

(22) Filed: Aug. 14, 2013

(30) Foreign Application Priority Data
Aug. 30, 2012 (JP) 2012-189817

(51) Int. Cl. H05K 5/00

(52) U.S. Cl. CPC H05K 5/0017
USPC 361/679.01

(57) ABSTRACT

A display apparatus includes a display main body, a reinforcement member, and a rear cover. The display main body is configured to display an image. The reinforcement member is fixed to a back surface of the display main body and configured to reinforce the display main body. The rear cover is configured to cover the back surface of the display main body with the reinforcement member exposed to outside.

### BACKGROUND

The present disclosure relates to a display apparatus, and particularly to a display apparatus that allows a reinforcement member for reinforcing strength of a casing to be also used for another purpose, for example.

For example, a rear cover provided on a back surface of a television set or the like is generally made by using plastic, plate, or the like.

Further, for a television set in related art, a thickness of a television set is being reduced, and a size thereof is being increased, so there arises a problem of an inadequate strength of a casing thereof.

In view of the above, a technique for reinforcing the strength by providing a reinforcement member between a back surface of a television set and a rear cover thereof has been proposed (see, for example, Japanese Patent Application Laid-open No. 2006-39062).

### SUMMARY

In a television set in related art, the inadequacy of the strength can be overcome by providing a reinforcement member, but the reinforcement member is difficult to be used for another purpose because the reinforcement member is covered with a rear cover.

That is, for example, in the television set in related art, the reinforcement member is difficult to be used as a handle or the like that is held when the television set is carried.

In view of the above-mentioned circumstances, it is desirable to make it possible to also use a reinforcement member for reinforcing a casing of a display apparatus for another purpose.

According to an embodiment of the present disclosure, there is provided a display apparatus including a display main body configured to display an image, a reinforcement member fixed to a back surface of the display main body and configured to reinforce the display main body, and a rear cover configured to cover the back surface of the display main body with the reinforcement member exposed to outside.

The rear cover may cover the back surface of the display main body with at least a part of the reinforcement member exposed to outside without being in contact with other members.

The display apparatus may further include a connection member connected to the back surface of the display main body. In the display apparatus, the reinforcement member may be fixed to the back surface of the display main body with the connection member intervened therebetween.

The rear cover may cover the connection member provided on the back surface of the display main body with the reinforcement member exposed to outside.

The reinforcement member may be constituted of a plurality of members that are capable of being taken apart.

The reinforcement member may be made of metal.

According to the embodiment of the present disclosure, the reinforcement member fixed to the back surface of the display main body that displays an image reinforces the display main body, and the back surface of the display main body is covered with the rear cover with the reinforcement member exposed to outside.

According to the embodiment of the present disclosure, it is possible to also use the reinforcement member for reinforcing the casing of the display apparatus for another purpose.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a diagram showing a back surface of a television set to which the present technology is applied;

FIG. 2 is a diagram showing an example in the case where a part of a reinforcement member is used as a handle;

FIG. 3 is a diagram showing an example in the case where the television set is fixed to a wall with a wire;

FIG. 4 is a diagram showing an example when the wire is tied to the handle;

FIG. 5 is a diagram showing an example of the reinforcement member;

FIG. 6 is a diagram showing another example of the reinforcement member;

FIG. 7 is a diagram showing an example of an appearance of a part of a back surface portion of the television set; and

FIG. 8 is a cross-sectional view showing a part of the television set.

### DETAILED DESCRIPTION OF EMBODIMENTS

Hereinafter, an embodiment of the present disclosure will be described. It should be noted that the description will be given in the following order.

1. Embodiment (Example in Case where Reinforcement Member is used as Handle, etc., in Addition to Purpose of Reinforcement)

2. Modified Example

### <1. Embodiment>

### (Example of Appearance of Television Set 1)

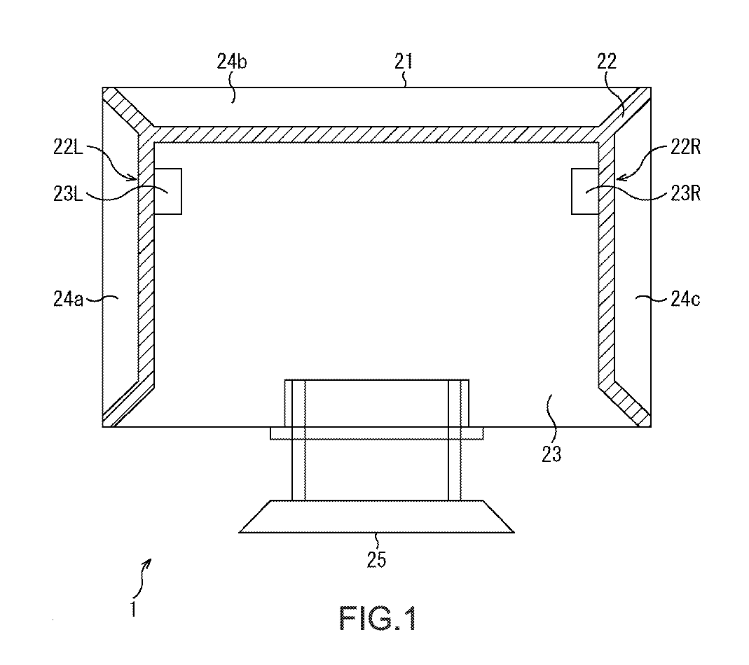

FIG. 1 is a diagram showing a back surface of a television set 1 according to this embodiment.

The television set 1 is mainly constituted of a display main body 21, a reinforcement member 22, rear covers 23 and 24a to 24c, and a stand 25.

The display main body 21 is a casing in which a display module for displaying an image is incorporated. That is, for example, in the display main body 21, a back light and a liquid crystal panel are incorporated as the display modules.

It should be noted that, in this embodiment, the assumption is made that the back light and the liquid crystal panel are incorporated in the display main body 21 as the display modules. However, the display modules incorporated in the display main body 21 are not limited to those.

In other words, for example, in the display main body 21, as the display modules, a plasma display panel, an organic EL (electroluminescence) panel, or the like can be incorporated.

Further, in the display main body 21, on the center portion of a back surface (surface shown in FIG. 1) of a display surface on which an image is displayed, a circuit and the like for performing image processing or the like are provided. The circuit and the like are covered with the rear cover 23 and protected.

The reinforcement member 22 is made of metal such as an aluminum alloy and is fixed to the back surface of the display main body 21, thereby reinforcing the display main body 21. The reinforcement member 22 can prevent (suppress) warp, breakage, or the like of the display main body 21.

It should be noted that the reinforcement member 22 is made of metal such as the aluminum alloy in this case, but the kind of the metal is not limited to the aluminum alloy. Further, the reinforcement member 22 may be made of a material different from metal.

That is, the reinforcement member 22 may be made of any material, as long as the reinforcement member 22 increases the stiffness of the display main body 21.

Further, as shown in FIG. 1, the reinforcement member 22 may be disposed so as to reinforce the entire display main body 21 or may be disposed on a part of the display main body 21 where the warp, the breakage, or the like is relatively likely to occur, for example.

In other words, the part where the reinforcement member 22 is disposed is not limited to the part as shown in FIG. 1, and the reinforcement member 22 can be disposed on any part.

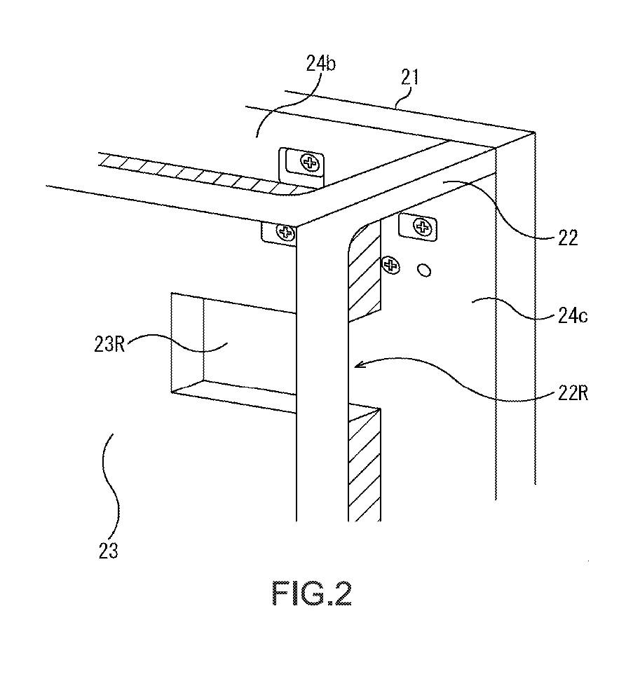

Further, in addition to the purpose of the reinforcement of the display main body 21, the reinforcement member 22 can be used for another purpose. This will be described in detail with reference to FIGS. 2 to 4.

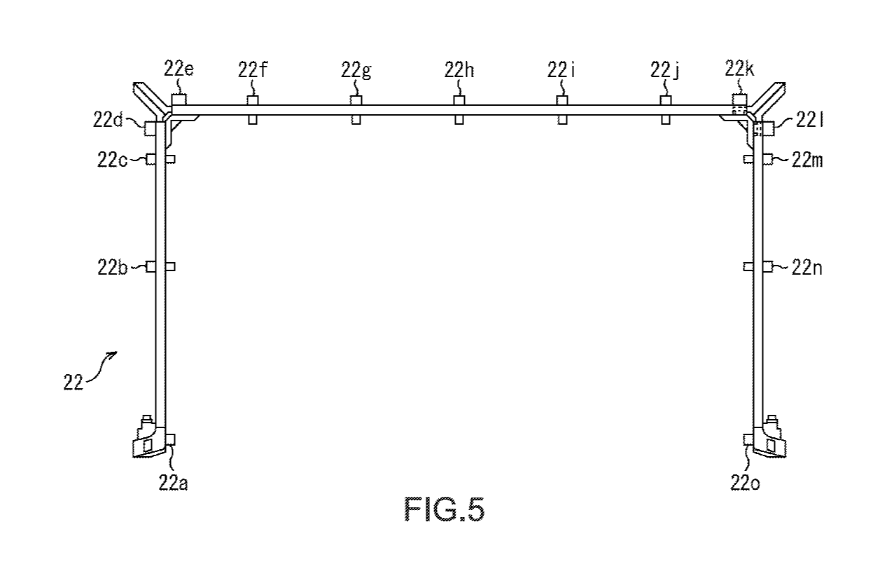

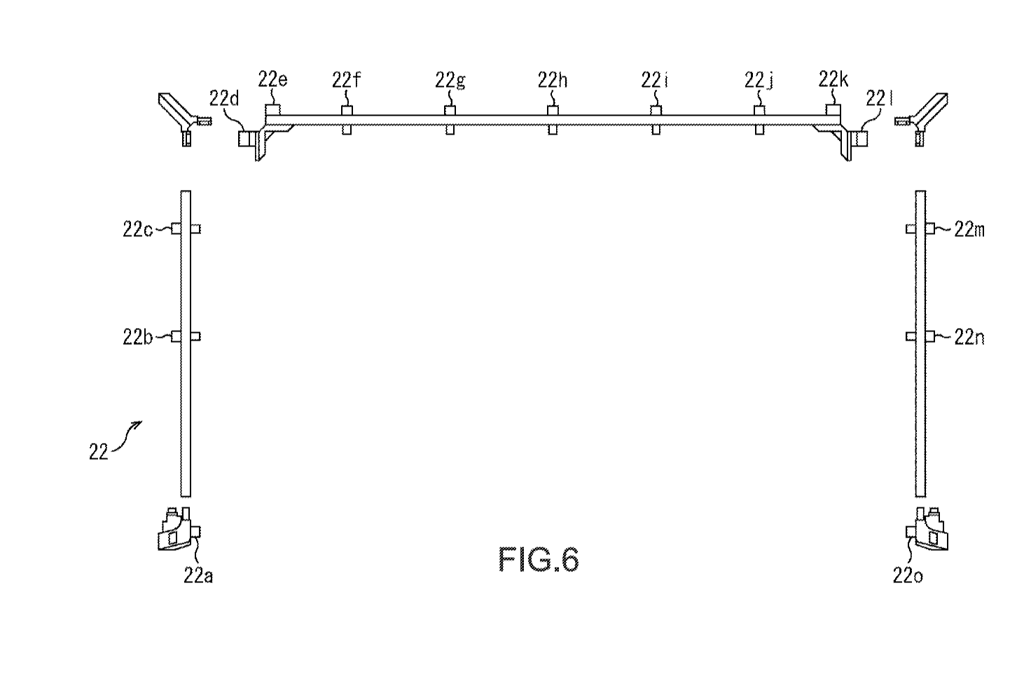

Further, for the reinforcement member 22, one member that is difficult to be taken apart or a member that can be taken apart can be used. This will be described in detail with reference to FIGS. 5 and 6.

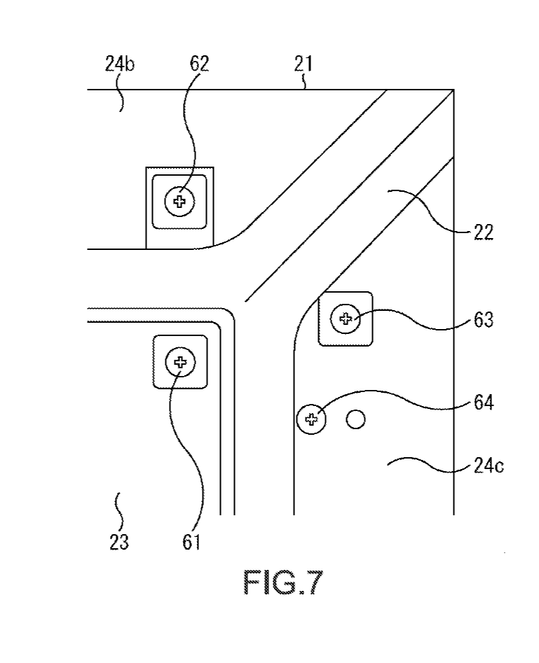

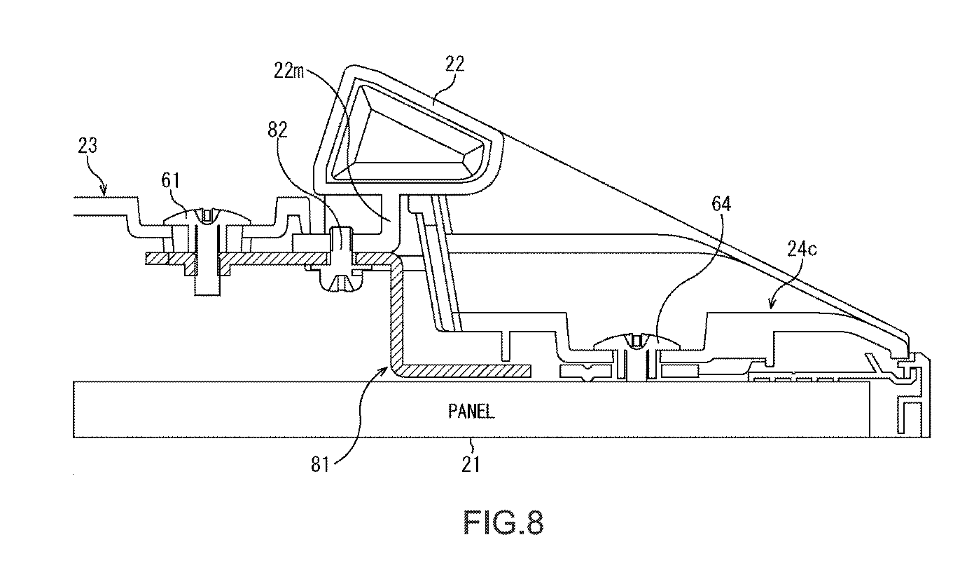

Further, the reinforcement member 22 is directly connected to the display main body 21 without intervening the rear cover 23 or the like therebetween. This will be described in detail with reference to FIGS. 7 and 8.

The rear cover 23 is a cover that covers the circuit and the like disposed on the center portion on the back surface of the display main body 21.

On the back surface of the television set 1, depressed portions 23L and 23R are formed so that the reinforcement member 22 can be used for another purpose. With this structure, parts 22L and 22R of the reinforcement member 22 can serve as handles 22L and 22R.

The rear covers 24a to 24c are covers that cover parts which are not covered with the rear cover 23 (part where the circuit and the like are not provided) on the back surface of the display main body 21.

Specifically, on the back surface of the display main body 21, the rear cover 24a covers a surface on the left side of the rear cover 23 in the figure, the rear cover 24b covers a surface on the upper side of the rear cover 23 in the figure, and the rear cover 24c covers a surface on the right side of the rear cover 23 in the figure.

It should be noted that the rear covers 23 and 24a to 24c cover the back surface of the display main body 21 with the reinforcement member 22 exposed to outside as shown in FIG. 1.

The stand 25 supports the display main body 21. The stand 25 is detachably attached to the display main body 21.

(Example in Case where the Reinforcement Member 22 is used as Handle 22R)

Subsequently, FIG. 2 is a diagram showing an example in the case where the part 22R of the reinforcement member 22 is used as the handle 22R.

It should be noted that the part 22L of the reinforcement member 22 is used as the handle 22L as in the case of the part 22R of the reinforcement member 22. Therefore, in FIG. 2, description about the part 22L of the reinforcement member 22 will be omitted, and only the part 22R of the reinforcement member 22 will be described.

As shown in FIG. 2, the rear cover 23 covers the back surface of the display main body 21 at a higher position than the rear covers 24a to 24c. This is because the rear cover 23 covers the back surface of the display main body 21 corresponding to the part where the circuit and the like are provided, unlike the rear covers 24a to 24c that directly cover the back surface of the display main body 21.

As shown in FIG. 2, in the reinforcement member 22, by forming the depressed portion 23R, the part 22R of the reinforcement member 22 which is not in contact with any member is used as the handle 22R.

With this structure, the part 22R of the reinforcement member 22 doubles as the handle 22R, with the result that it is possible to carry the television set 1 more easily.

(Example in Case where Reinforcement Member 22 is used as Attachment Portion of Wire 41)

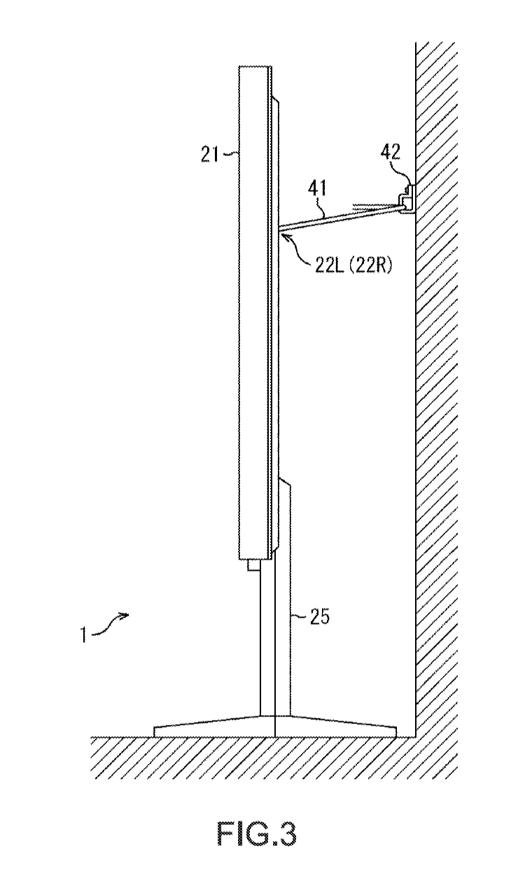

Subsequently, FIG. 3 is a diagram showing an example of a state of the television set 1 in the case where the television set 1 is fixed to a wall with a wire 41 or the like.

As shown in FIG. 3, the wire 41 tied to the handles 22L and 22R of the television set 1 is fixed to a ring-shaped fixation device 42 nailed to the wall, with the result that it is possible to prevent the television set 1 from toppling, for example.

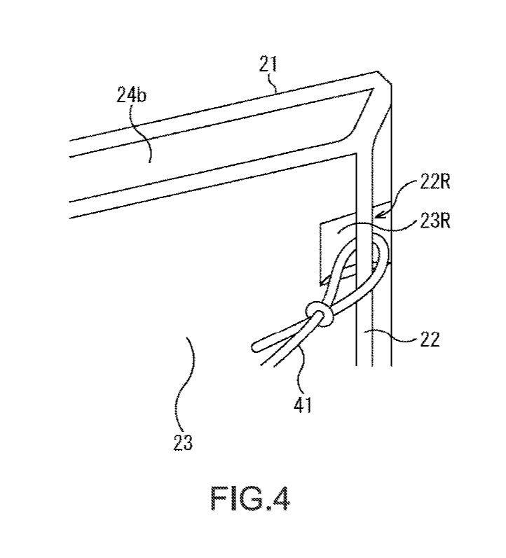

Next, FIG. 4 is a diagram showing an example when the wire 41 is tied to the handle 22R as the part of the reinforcement member 22.

It should be noted that in FIG. 4, to avoid complication of the figure, the depressed portion 23R and the like shown in FIG. 2 are simplified.

As shown in FIG. 4, one end of the wire 41 is tied to the handle 22R. The other end of the wire 41 is caused to pass through a ring of the ring-shaped fixation device 42 (FIG. 3) and is then tied to the other handle 22L.

Like the handle 22R, to the handle 22L, the other end of the wire 41 is tied. Therefore, in FIG. 4, a state in which the other end of the wire 41 is tied to the handle 22L is not shown.

In this embodiment, the reinforcement member 22 can double as the handles 22L and 22R or the like, so it is possible to provide the handles 22L and 22R with the thin thickness of the television set 1 maintained without deteriorating the design.

Further, in this embodiment, for example, as compared to the case where the handles 22L and 22R and a member for reinforcing the display main body 21 are separately provided, it is possible to reinforce the display main body 21 and attach the handles 22L and 22R with a smaller number of materials.

### (Example of Reinforcement Member 22)

Next, FIG. 5 is a diagram showing an example of the reinforcement member 22.

As shown in FIG. 5, the reinforcement member 22 is formed as one member that is difficult to be taken apart, for example.

Further, the reinforcement member 22 has attachment portions 22a to 22o which are attached to the display main body 21. It should be noted that the number of attachment portions 22a to 22o is not limited to this, and any number of attachment portions can be used. In addition, positions of the attachment portions 22a to 22o can be arbitrarily set.

Further, shapes of the attachment portions 22a to 22o are not limited to the shape shown in FIG. 5 and may be any shape, as long as the attachment portions 22a to 22o can be attached to the display main body 21.

In the reinforcement member 22, a method of attaching the attachment portions 22a to 22o to the display main body 21 will be described in detail with reference to FIGS. 7 and 8.

The reinforcement member 22 may be formed as one member that is not taken apart as shown in FIG. 5 or may be formed of a plurality of parts that can be taken apart as shown in FIG. 6.

Subsequently, FIG. 7 is a diagram showing an example of an appearance of an upper right part of the television set 1 of FIG. 1 in detail.

Screws 61, 62, and 63 fix the rear covers 23, 24b, and 24c to the display main body 21, respectively. A screw 64 fixes the rear cover 24c to the display main body 21.

Next, FIG. 8 is a cross-sectional view showing the television set 1 shown in FIG. 7.

As shown in FIG. 8, the reinforcement member 22 has an attachment portion 22m having an L-letter shape, for example, and the attachment portion 22m is fixed to the back surface of display main body 21 with a connection member 81 (indicated by shaded area) intervened therebetween.

The connection member 81 is connected to the back surface of the display main body 21 and is connected with the attachment portion 22m of the reinforcement member 22 with a screw 82. As a result, the reinforcement member 22 is fixed to the back surface of the display main body 21 with the connection member 81 which is connected to the attachment portion 22m intervened therebetween.

It should be noted that the connection member 81 can be made of a different material from the reinforcement member 22, and the connection member 81 can be integrally formed as a part of the reinforcement member 22.

In addition, the connection member 81 is connected to the rear cover 23 with the screw 61. With this structure, the rear cover 23 is fixed to the back surface of the display main body 21 with the connection member 81 intervened therebetween. Further, the rear cover 23 covers the connection member 81 provided on the back surface of the display main body 21 with the reinforcement member 22 exposed to outside.

The rear cover 24c is fixed to the display main body 21 with the screw 62. In addition, although not shown in FIG. 8, the rear covers 24a and 24b are also fixed to the display main body 21 in the same way. Further, the rear cover 24c covers the connection member 81 provided on the back surface of the display main body 21 with the reinforcement member 22 exposed to the outside. The same holds true for the rear covers 24a and 24b.

### <2. Modified Example>

In the embodiment, the television set 1 having the liquid crystal panel, the plasma display panel, the organic EL panel, or the like is described. The present technology can be applied to any display apparatus that displays an image.

It should be noted that the present disclosure can take the following configurations.

(1) A display apparatus, including:

a display main body configured to display an image;

a reinforcement member fixed to a back surface of the display main body and configured to reinforce the display main body; and

a rear cover configured to cover the back surface of the display main body with the reinforcement member exposed to outside.

(2) The display apparatus according to Item (1), in which

the rear cover covers the back surface of the display main body with at least a part of the reinforcement member exposed to outside without being in contact with other members.

(3) The display apparatus according to Item (1) or (2), further including

a connection member connected to the back surface of the display main body, in which

the reinforcement member is fixed to the back surface of the display main body with the connection member intervened therebetween.

(4) The display apparatus according to Item (3), in which

the rear cover covers the connection member provided on the back surface of the display main body with the reinforcement member exposed to outside.

(5) The display apparatus according to any one of Items (1) to (4), in which

the reinforcement member is constituted of a plurality of members that are capable of being taken apart.

(6) The display apparatus according to any one of Items (1) to (5), in which

the reinforcement member is made of metal.

The present disclosure contains subject matter related to that disclosed in Japanese Priority Patent Application JP 2012-189817 filed in the Japan Patent Office on Aug. 30, 2012, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display apparatus, comprising:
a display main body configured to display an image;
a reinforcement member fixed to a back surface of the display main body and configured to reinforce the display main body; and
a rear cover configured to cover the back surface of the display main body with the reinforcement member exposed to outside.

2. The display apparatus according to claim 1, wherein
the rear cover covers the back surface of the display main body with at least a part of the reinforcement member exposed to outside without being in contact with other members.

3. The display apparatus according to claim 2, further comprising
a connection member connected to the back surface of the display main body, wherein
the reinforcement member is fixed to the back surface of the display main body with the connection member intervened therebetween.

4. The display apparatus according to claim 3, wherein
the rear cover covers the connection member provided on the back surface of the display main body with the reinforcement member exposed to outside.

5. The display apparatus according to claim 4, wherein
the reinforcement member is constituted of a plurality of members that are capable of being taken apart.

6. The display apparatus according to claim 5, wherein the reinforcement member is made of metal.
